(19) United States
(12) Patent Application Publication
(10) Pub. No.: US 2016/0248016 A1
(43) Pub. Date: Aug. 25, 2016

(54) SUBSTRATE PACKAGING METHOD

(71) Applicant: SHENZHEN CHINA STAR OPTOELECTRONICS TECHNOLOGY CO., LTD., Guangdong (CN)

(72) Inventor: Yawei LIU, Shenzhen, Guangdong (CN)

(73) Assignee: Shenzhen China Star Optoelectronics Technology Co., Ltd., Shenzhen, Guangdong (CN)

(21) Appl. No.: 14/378,425

(22) PCT Filed: Jul. 2, 2014
(86) PCT No.: PCT/CN2014/081445

§ 371 Date: Aug. 13, 2014

(30) Foreign Application Priority Data
Jun. 17, 2014 (CN) 201410271488.1

(51) Int. Cl. H01L 51/00; H01L 51/52; H01L 51/56

(52) U.S. Cl. CPC H01L 51/0024; H01L 51/56; H01L 51/0017; H01L 51/5246

(57) ABSTRACT

The present invention provides a substrate packaging method, comprising steps of: step 1: providing a base substrate and a packaging substrate; step 2: disposing a circle of inorganic insulation film on the packaging substrate; step 3: disposing a circle of ultraviolet (UV) sealant outside the circle of inorganic insulation film on the packaging substrate; step 4: oppositely adhering the packaging substrate to the base substrate; and step 5, utilizing an ultraviolet (UV) light source to irradiate the UV sealant so as to cure the UV sealant in order to package the packaging substrate and the base substrate. The packaging method can improve the packaging effect, increase the ability for resisting the water vapor and the oxygen, and extend the life of the OLED device.

### BACKGROUND OF THE INVENTION

1. Field of the Invention

The present invention relates to a display technology field, and more particularly to a substrate packaging method.

2. Description of Related Art

In the display technology field, the liquid crystal display (LCD), the organic light emitting diode (OLED) device, and other flat panel display technology have been gradually replaced the CRT monitor. The planar light source technology is a new type of light source. The technology development of the planar light source technology is close to the market-oriented and mass production level. In the flat panel display and the planar light source technology, adhering two pieces of flat panel glasses is very important. The packaging result will directly affect the performance of the display.

The ultraviolet (UV) curing technology is the earliest and the most commonly used technology for the LCD/OLED packaging. The ultraviolet (UV) curing technology has the following characteristics: (1) does not use a solvent or only uses a small amount of solvent, reducing the environment pollution by the solvent; (2) low energy consumption, capable of curing at a low temperature, suitable for heat-sensitive materials; (3) fast curing speed, high-efficiency, capable of applying at high-speed production lines, and the occupied area is small for the curing equipment. However, the UV sealant used in the UV curing technology is an organic material. The gaps among molecules of the UV sealant are larger. The water vapor and oxygen are easy to enter into an area sealed by the UV sealant. As a result, the UV curing method is more suitable for an application which is less sensitive to the water vapor and oxygen such as a liquid crystal display (LCD). Because the OLED device is very sensitive to the water vapor and oxygen, therefore, when using the UV curing method for packaging, a drying agent is usually used inside the OLED device so as to reduce the water vapor entering the area sealed by the UV sealant through the gaps. As a result, the life of the OLED device is increased.

Currently, for the OLED device using the UV curing method for packaging, a main research direction is to find an UV sealant with a lower permeation rate of the water vapor. To meet the above requirement, the molecules of the UV sealant have to be stacked more closely after curing such that the gaps among the molecules for the water vapor to enter become narrow, and the vapor permeation rate becomes smaller.

The frit packaging technology is a current development technology for a new flat panel glass packaging. In China, there are almost no relevant literature reports. The frit packaging technology is mixing glass powders with a solvent to become a solution with a certain viscosity, coating the solution on the glass for packaging, and heating to remove the solvent. After the glass for packaging is adhered, using a laser to melt the glass powders in order to bond the two flat glasses together. Because the frit packaging technology utilizes inorganic materials for packaging, the water vapor and oxygen preventing ability is very strong. The frit packaging technology is very suitable for the OLED device which is very sensitive to the water vapor and oxygen. Currently, the technology patents for the frit packaging technology are owned by a few foreign companies.

FIG. 1 and FIG. 2 are schematic packaging diagrams of a conventional UV curing method of a substrate. The UV packaging method is only coating an UV sealant 200 on a surface of the packaging substrate 100 and is oppositely adhering the packaging substrate 100 to a thin-film-transistor (TFT) substrate 300. After irradiating the UV sealant by the UV light to cure the UV sealant, the packaging of the packaging substrate 100 and the TFT substrate 300 is realized.

Because the OLED device 400 disposed on the TFT substrate 300 is very sensitive to the water vapor and the oxygen, but the current UV curing method is poor in preventing the water vapor and the oxygen, the drying agent is required to decrease the water vapor entering the sealed area through the UV sealant in order to extend the life of the OLED device. However, the UV curing method is only suitable for a bottom emission OLED device. The frit packaging has a better effect for preventing the water vapor. However, the fabrication process using the frit packaging is complicated and the related equipment is expensive.

### SUMMARY OF THE INVENTION

The purpose of the present invention is to provide a substrate packaging method. The method can improve the packaging effect, increase the ability for resisting the water vapor and the oxygen, and extend the life of the OLED device. Besides, the method does not require the drying agent, and is suitable for a bottom emission, a top emission or a double-side display OLED device.

To achieve the above purpose, the present invention provides: a substrate packaging method, comprising steps of:

step 1: providing a base substrate and a packaging substrate;

step 2: disposing a circle of inorganic insulation film on the packaging substrate;

step 3: disposing a circle of ultraviolet (UV) sealant outside the circle of inorganic insulation film on the packaging substrate;

step 4: oppositely adhering the packaging substrate to the base substrate; and

step 5, utilizing an ultraviolet (UV) light source to irradiate the UV sealant so as to cure the UV sealant in order to package the packaging substrate and the base substrate.

Wherein, the base substrate is a thin-film-transistor (TFT) substrate and the packaging substrate is a glass plate.

Wherein, the base substrate is provided with an OLED device.

Wherein, the packaging substrate in the step 1 is disposed with a coating position for disposing the UV sealant, the inorganic insulation film disposed in the step 2 is located inside the coating position, the UV sealant disposed in the step 3 is located on the coating position, and the UV sealant is disposed on the packaging substrate by a coating method.

Wherein, the inorganic insulation film is made of silicon dioxide (SiO2) or silicon nitride (SiNx).

Wherein, the step 2 further comprises steps of disposing a circle of metal layer on the packaging substrate in advance and disposing the inorganic insulation film on the metal layer.

Wherein, the metal layer is made of molybdenum.

Wherein, when fabricating an alignment mark of the packaging substrate, the inorganic insulation film is formed simultaneously; the inorganic insulation film is fabricated by coating using a chemical vapor deposition (CVD) and etching after coated.

Wherein, a width of the inorganic insulation film ranges from 20 um to 2000 um; a height of the inorganic insulation film ranges from 3 um to 50 um; the inorganic insulation film on the same packaging substrate is the same in width and height; after adhering the packaging substrate to the base substrate in the step 4, a width of the UV sealant is controlled within 1 mm to 5 mm; a height of the UV sealant is greater than the height of the inorganic insulation film in the step 3.

Wherein, an outer edge of the inorganic insulation film is located at a distance of 0.5 mm to 5 mm from a center line of the coating position.

The present invention also provides a substrate packaging method, comprising steps of:

step 1: providing a base substrate and a packaging substrate;

step 2: disposing a circle of inorganic insulation film on the packaging substrate;

step 3: disposing a circle of ultraviolet (UV) sealant outside the circle of inorganic insulation film on the packaging substrate;

step 4: oppositely adhering the packaging substrate to the base substrate; and

step 5, utilizing an ultraviolet (UV) light source to irradiate the UV sealant so as to cure the UV sealant in order to package the packaging substrate and the base substrate;

wherein, the base substrate is a thin-film-transistor (TFT) substrate, and the packaging substrate is a glass plate;
wherein, the base substrate is provided with an OLED device;
wherein, the packaging substrate in the step 1 is disposed with a coating position for disposing the UV sealant, the inorganic insulation film disposed in the step 2 is located inside the coating position, the UV sealant disposed in the step 3 is located on the coating position, and the UV sealant is disposed on the packaging substrate by a coating method;

wherein, the inorganic insulation film is made of silicon dioxide (SiO2) or silicon nitride (SiNx);

wherein, when fabricating an alignment mark of the packaging substrate, the inorganic insulation film is formed simultaneously; the inorganic insulation film is fabricated by coating using a chemical vapor deposition (CVD) and etching after coated.

wherein, a width of the inorganic insulation film ranges from 20 um to 2000 um; a height of the inorganic insulation film ranges from 3 um to 50 um; the inorganic insulation film on the same packaging substrate is the same in width and height; after adhering the packaging substrate to the base substrate in the step 4, a width of the UV sealant is controlled within 1 mm to 5 mm; a height of the UV sealant is greater than the height of the inorganic insulation film in the step 3; and

wherein, an outer edge of the inorganic insulation film is located at a distance of 0.5 mm to 5 mm from a center line of the coating position.

Beneficial Effects:

The substrate packaging method of the present invention is simple and easy to operate. The packaging method combines the advantages of the UV curing method and the frit packaging. Through disposing a circle of inorganic insulation film on the packaging substrate and disposing the inorganic insulation film inside the UV sealant, the present invention utilizes the inorganic insulation film to resist the water vapor and the oxygen in order to improve the packaging effect, increase the ability for resisting the water vapor and the oxygen, and extend the life of the OLED device. Besides, the present invention does not require the drying agent, and is suitable for a bottom emission, a top emission or a double-side display OLED device.

### BRIEF DESCRIPTION OF THE DRAWINGS

FIG. 1 is a schematic top view of an UV curing method of a substrate according to the prior art;

FIG. 2 is a schematic sectional view of an UV curing method of a substrate according to the prior art;

FIG. 3 is a flowchart of a substrate packaging method according to the present invention;

FIG. 4 a schematic top view of the substrate packaging method according to the step 1 of the present invention;

FIG. 5 a schematic top view of the substrate packaging method according to the step 2 of the present invention;

FIG. 6 is a schematic sectional view of the substrate packaging method according to an embodiment of the step 2 of the present invention;

FIG. 7 is a schematic sectional view of the substrate packaging method according to another embodiment of the step 2 of the present invention;

FIG. 8 a schematic top view of the substrate packaging method according to the step 3 of the present invention;

FIG. 9 is a schematic sectional view of the substrate packaging method according to the step 3 of the present invention; and

FIG. 10 is a schematic sectional view of the substrate packaging method according to the step 4 of the present invention.

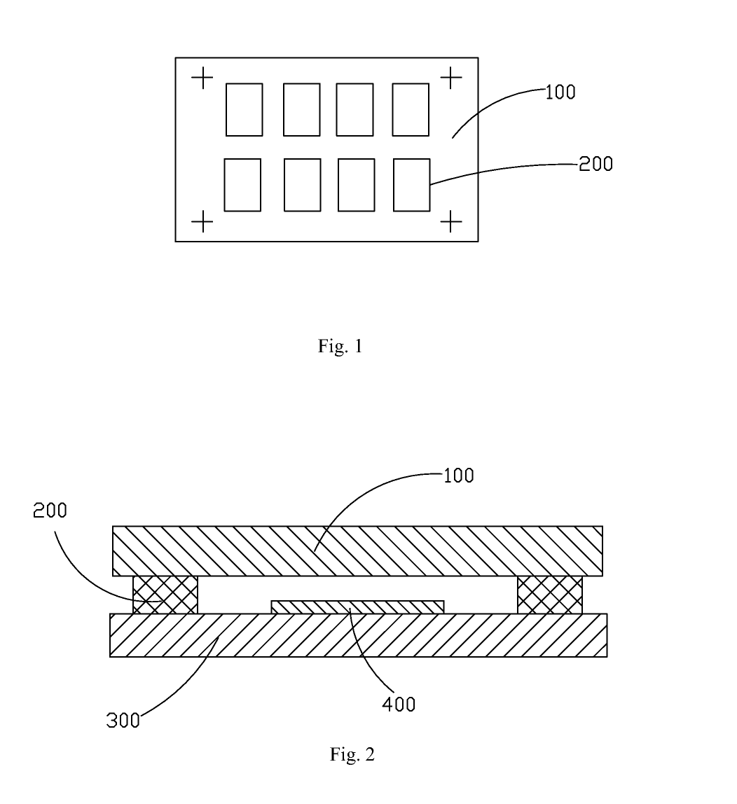

### DETAILED DESCRIPTION OF THE PREFERRED EMBODIMENT

The following content combines with the preferred embodiment and the accompanying drawings for a detailed description of the present invention.

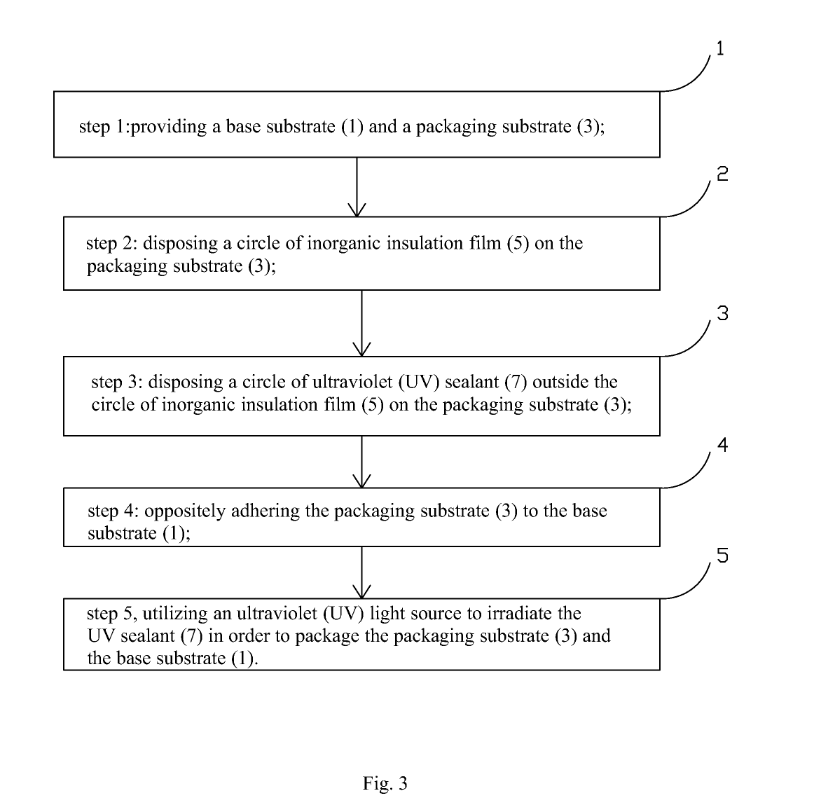

With reference to FIG. 3 to FIG. 10, the present invention provides a substrate packaging method comprising the steps of:

Step 1: providing a base substrate 1, and a packaging substrate 3;

Step 2: disposing a circle of inorganic insulation film 5 on the packaging substrate 3;

Step 3: disposing a circle of an ultraviolet (UV) sealant 7 outside the circle of inorganic insulation film 5 on the packaging substrate 3;

Step 4: oppositely adhering the packaging substrate 3 to the base substrate 1;

Step 5, utilizing an UV light source to irradiate the UV sealant 7 so as to cure the UV sealant 7 in order to package the packaging substrate 3 and the base substrate 1.

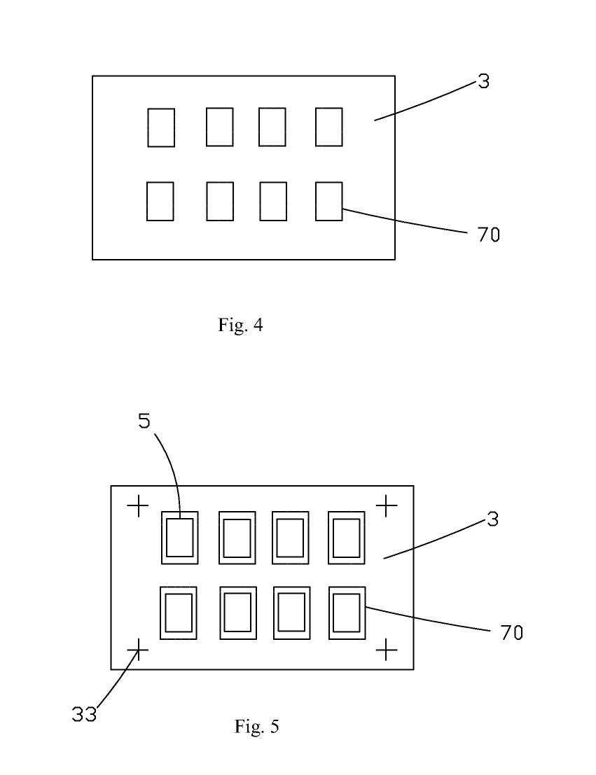

Specifically, the base substrate 1 in the step 1 is a thin-film-transistor (TFT) substrate, and the packaging substrate 3 is a glass plate. Furthermore, the base substrate 1 provides with an OLED device 11. As shown in FIG. 4, the packaging substrate 3 is disposed with coating positions 70 for the UV sealant in advance. The coating positions 70 provide a position reference for the inorganic insulation film 5 and the UV sealant 7 in the following steps.

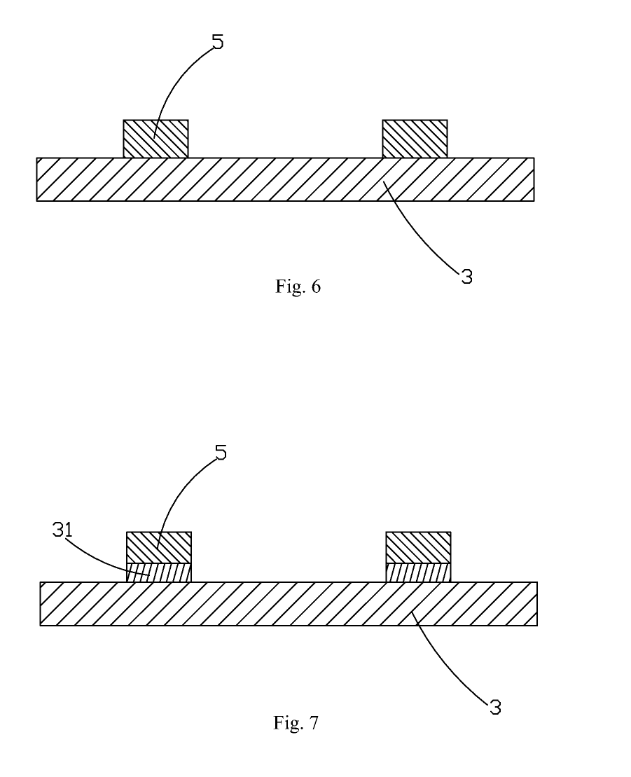

With reference to FIG. 5 and FIG. 6, in the step, when fabricating alignment marks 33 of the packaging substrate 3, the inorganic insulation film 5 is formed simultaneously. The inorganic insulation film 5 is made of silicon dioxide (SiO2) or silicon nitride (SiNx). Besides, the inorganic insulation film 5 is fabricated by coating using a chemical vapor deposition (CVD) and etching after coated. The inorganic insulation film 5 has excellent ability to resist the water vapor and oxygen. A width of the inorganic insulation film ranges from 20 um to 2000 um. A height of the inorganic insulation film ranges from 3 um to 50 um. Besides, the inorganic insulation film 5 in the same packaging substrate 3 is the same in width and height. It should be noted particularly that the inorganic insulation film 5 is disposed inside the coating position 70, and the outer edge of the inorganic insulation film 5 is located at a distance of 0.5 mm to 5 mm from a center line of the coating position 70.

FIG. 6 is a schematic sectional view of the substrate packaging method according to an embodiment of the step 2 of the present invention. In the embodiment, the inorganic insulating film 5 is directly formed on the surface of the packaging substrate 3.

FIG. 7 is a schematic sectional view of the substrate packaging method according to another embodiment of the step 2 of the present invention. A circle of metal layer 31 is formed on the surface of the packaging substrate 3. Preferably, the metal layer 31 is made of molybdenum. The inorganic insulation film 5 is disposed on the metal layer 31.

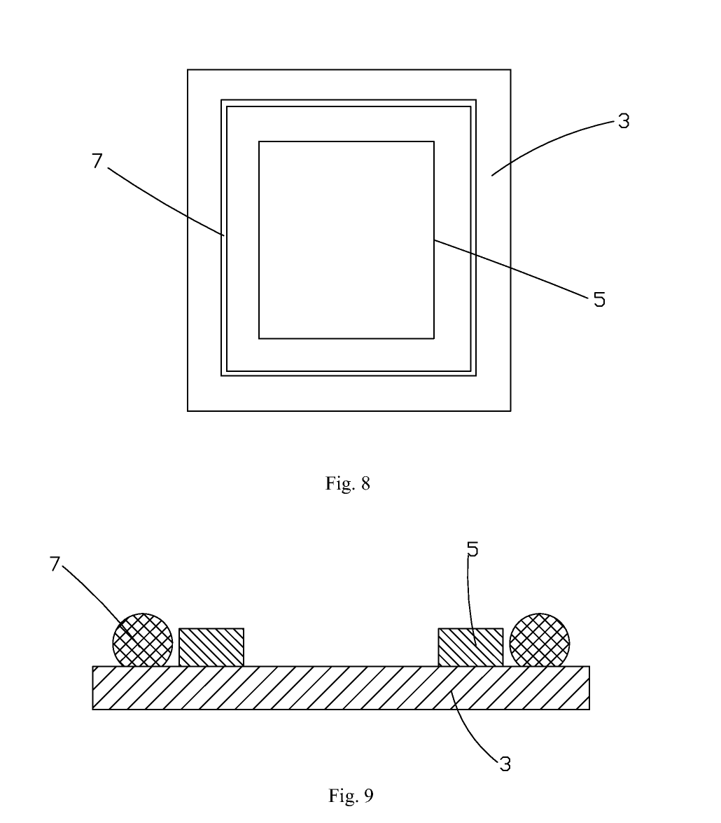

With reference to FIG. 8, FIG. 9, in the step 3, a circle of UV sealant 7 is coated outside the inorganic insulation film 5 on the packaging substrate 3. Precisely, the UV sealant 7 is coated on the coating position 70, and the height of the UV sealant 7 is greater than the height of the inorganic insulation film 5.

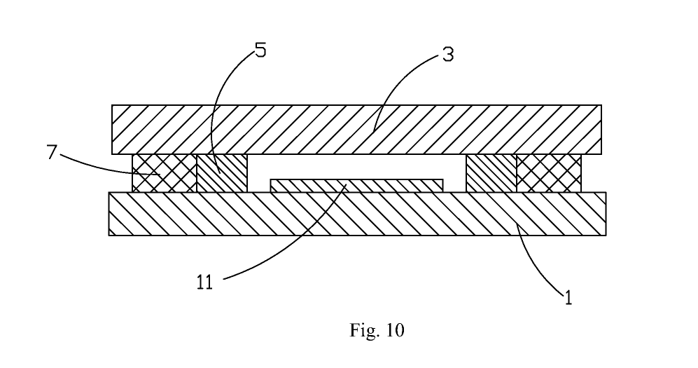

With reference to FIG. 10, after adhering the packaging substrate 3 to the base substrate 1 in the step 4, the width of the UV sealant 7 is controlled within 1 mm to 5 mm.

Finally, the step 5 is executed. In the step 5, utilizing an UV light source to irradiate the UV sealant 7 so as to cure the UV sealant 7 in order to package the packaging substrate 3 and the base substrate 1.

In summary, the substrate packaging method of the present invention is simple and easy to operate. The packaging method combines the advantages of the UV curing method and the frit packaging. Through disposing a circle of inorganic insulation film on the packaging substrate and disposing the inorganic insulation film inside the UV sealant, the present invention utilizes the inorganic insulation film to resist the water vapor and the oxygen in order to improve the packaging effect, increase the ability for resisting the water vapor and the oxygen, and extend the life of the OLED device. Besides, the present invention does not require the drying agent, and is suitable for a bottom emission, a top emission or a double-side display OLED device.

The above embodiments of the present invention are not used to limit the claims of this invention. Any use of the content in the specification or in the drawings of the present invention which produces equivalent structures or equivalent processes, or directly or indirectly used in other related technical fields is still covered by the claims in the present invention.

What is claimed is:

1. A substrate packaging method, comprising steps of:
step 1: providing a base substrate and a packaging substrate;
step 2: disposing a circle of inorganic insulation film on the packaging substrate;
step 3: disposing a circle of ultraviolet (UV) sealant outside the circle of inorganic insulation film on the packaging substrate;
step 4: oppositely adhering the packaging substrate to the base substrate; and
step 5, utilizing an ultraviolet (UV) light source to irradiate the UV sealant so as to cure the UV sealant in order to package the packaging substrate and the base substrate.

2. The substrate packaging method according to claim 1, wherein, the base substrate is a thin-film-transistor (TFT) substrate and the packaging substrate is a glass plate.

3. The substrate packaging method according to claim 2, wherein, the base substrate is provided with an OLED device.

4. The substrate packaging method according to claim 1, wherein, the packaging substrate in the step 1 is disposed with a coating position for disposing the UV sealant, the inorganic insulation film disposed in the step 2 is located inside the coating position, the UV sealant disposed in the step 3 is located on the coating position, and the UV sealant is disposed on the packaging substrate by a coating method.

5. The substrate packaging method according to claim 4, wherein, the inorganic insulation film is made of silicon dioxide (SiO2) or silicon nitride (SiNx).

6. The substrate packaging method according to claim 1, wherein, the step 2 further comprises steps of disposing a circle of metal layer on the packaging substrate in advance and disposing the inorganic insulation film on the metal layer.

7. The substrate packaging method according to claim 6, wherein, the metal layer is made of molybdenum.

8. The substrate packaging method according to claim 1, wherein, when fabricating an alignment mark of the packaging substrate, the inorganic insulation film is formed simultaneously; the inorganic insulation film is fabricated by coating using a chemical vapor deposition (CVD) and etching after coated.

9. The substrate packaging method according to claim 1, wherein, a width of the inorganic insulation film ranges from 20 um to 2000 um; a height of the inorganic insulation film ranges from 3 um to 50 um; the inorganic insulation film on the same packaging substrate is the same in width and height; after adhering the packaging substrate to the base substrate in the step 4, a width of the UV sealant is controlled within 1 mm to 5 mm; a height of the UV sealant is greater than the height of the inorganic insulation film in the step 3.

10. The substrate packaging method according to claim 4, wherein, an outer edge of the inorganic insulation film is located at a distance of 0.5 mm to 5 mm from a center line of the coating position.

11. A substrate packaging method, comprising steps of:
step 1: providing a base substrate and a packaging substrate;
step 2: disposing a circle of inorganic insulation film on the packaging substrate;
step 3: disposing a circle of ultraviolet (UV) sealant outside the circle of inorganic insulation film on the packaging substrate;
step 4: oppositely adhering the packaging substrate to the base substrate; and
step 5, utilizing an ultraviolet (UV) light source to irradiate the UV sealant so as to cure the UV sealant in order to package the packaging substrate and the base substrate;
wherein, the base substrate is a thin-film-transistor (TFT) substrate, and the packaging substrate is a glass plate;
wherein, the base substrate is provided with an OLED device;
wherein, the packaging substrate in the step 1 is disposed with a coating position for disposing the UV sealant, the inorganic insulation film disposed in the step 2 is located inside the coating position, the UV sealant disposed in the step 3 is located on the coating position, and the UV sealant is disposed on the packaging substrate by a coating method;
wherein, the inorganic insulation film is made of silicon dioxide (SiO2) or silicon nitride (SiNx);
wherein, when fabricating an alignment mark of the packaging substrate, the inorganic insulation film is formed simultaneously; the inorganic insulation film is fabricated by coating using a chemical vapor deposition (CVD) and etching after coated.
wherein, a width of the inorganic insulation film ranges from 20 um to 2000 um; a height of the inorganic insulation film ranges from 3 um to 50 um; the inorganic insulation film on the same packaging substrate is the same in width and height; after adhering the packaging substrate to the base substrate in the step 4, a width of the UV sealant is controlled within 1 mm to 5 mm; a height of the UV sealant is greater than the height of the inorganic insulation film in the step 3; and
wherein, an outer edge of the inorganic insulation film is located at a distance of 0.5 mm to 5 mm from a center line of the coating position.
